(19) United States
(12) Patent Application Publication
(10) Pub. No.: US 2025/0138053 A1
(43) Pub. Date: May 1, 2025

(54) ANALOG FRONT-END CHIP AND OSCILLOSCOPE

(71) Applicant: RIGOL TECHNOLOGIES CO., LTD., Jiangsu (CN)

(72) Inventors: Bo YAN, Jiangsu (CN); Jianwei Li, Jiangsu (CN); Chaomin Fang, Jiangsu (CN); Junzhou Luo, Jiangsu (CN); Yue Wang, Jiangsu (CN)

(73) Assignee: RIGOL TECHNOLOGIES CO., LTD., Jiangsu (CN)

(21) Appl. No.: 19/007,254

(22) Filed: Dec. 31, 2024

Related U.S. Application Data
(63) Continuation of application No. PCT/CN2023/084026, filed on Mar. 27, 2023.

(30) Foreign Application Priority Data
Jul. 29, 2022 (CN) 202210905289.6

(51) Int. Cl. G01R 13/02; H03G 3/00

(52) U.S. Cl. CPC G01R 13/0218; H03G 3/001

(57) ABSTRACT

An analog front-end chip and an oscilloscope are provided. The analog front-end chip is integrated with an input buffer module, a variable gain amplification module, and at least two output branches. An input end of the input buffer module is configured as an input end of the analog front-end chip, and an output end of the input buffer module is electrically connected to an input end of the variable gain amplification module. An input end of each of the output branches is electrically connected to an output end of the variable gain amplification module, and an output end of each of the output branches is configured as an output end of the analog front-end chip, wherein each of the output branches includes an output buffer module.

### CROSS-REFERENCE TO RELATED APPLICATIONS

The present disclosure is a Continuation Application of International Application No. PCT/CN2023/084026, filed on Mar. 27, 2023, which claims the priority of the Chinese patent application No. 202210905289.6, filed with the China National Intellectual Property Administration on Jul. 29, 2022, the entire contents of which are hereby incorporated by reference.

### TECHNICAL FIELD

The present disclosure generally relates to the technical field of data collection, for example, to an analog front-end chip and an oscilloscope.

### BACKGROUND

An analog front-end module of an oscilloscope is a crucial performance indicator and the core of the oscilloscope. In many cases, the bandwidth of a test signal of the oscilloscope is determined by the bandwidth of the analog front-end, which directly affects the oscilloscope's background noise and range. The main performance indicators of the analog front-end that affect the oscilloscope may include: analog bandwidth including the amplitude-frequency response characteristics of a measured signal, which is manifested as a rise time indicator and an overshoot performance indicator in the time domain; a dynamic range of an input signal amplitude (a range from the minimum vertical sensitivity to the maximum vertical sensitivity of non-digital processing); initial error characteristic and temperature drift characteristics of the two indicators of DC gain accuracy and offset accuracy; influence of input impedance characteristics (parasitic capacitance due to resistors in parallel) on a measured circuit with or without a probe. The analog front-end may attenuate, amplify, and condition the input signal, while the system noise is also amplified. If the oscilloscope's analog front-end is badly designed, the system noise will increase, and a desired small test signal may be not captured. If it is observed in the frequency domain, this noise will cause a decrease in the signal-to-noise ratio and an increase in the baseline noise. If the isolation between signal channels is insufficient, signals from other channels will cause significant interference to the measured signal. Meanwhile, the linearity and anti-saturation capability of the analog front-end are crucial.

However, in related technologies, the analog front-end is constructed using discrete devices, which makes it difficult to achieve high bandwidth and also occupies a relatively large area.

### SUMMARY

The present disclosure provides an analog front-end chip and an oscilloscope to reduce the area occupied by the analog front-end chip and achieve high bandwidth of the analog front-end chip.

According to one aspect of the present disclosure, an analog front-end chip is provided, and the analog front-end chip is integrated with an input buffer module, a variable gain amplification module, and at least two output branches, wherein
an input end of the input buffer module is configured as an input end of the analog front-end chip, and an output end of the input buffer module is electrically connected to an input end of the variable gain amplification module; and
an input end of each of the output branches is electrically connected to an output end of the variable gain amplification module, and an output end of each of the output branches is configured as an output end of the analog front-end chip, wherein each of the output branches includes an output buffer module.

According to another aspect of the present disclosure, an oscilloscope is provided, which includes the above-mentioned analog front-end chip.

### BRIEF DESCRIPTION OF DRAWINGS

In order to more clearly illustrate the embodiments of the present disclosure, the drawings required for use in the description of the embodiments will be briefly introduced below. The drawings described below are only some embodiments of the present disclosure. For those skilled in the art, other drawings can be obtained based on these drawings without creative work.

FIG. 1 is a schematic diagram of a circuit structure of an analog front-end chip provided in an embodiment of the present disclosure;

FIG. 2 is a schematic diagram of a circuit structure of another analog front-end chip provided in an embodiment of the present disclosure;

FIG. 3 is a schematic diagram of a circuit structure of another analog front-end chip provided in an embodiment of the present disclosure;

FIG. 4 is a schematic diagram of a circuit structure of another analog front-end chip provided in an embodiment of the present disclosure;

FIG. 5 is a schematic diagram of a circuit structure of another analog front-end chip provided in an embodiment of the present disclosure;

FIG. 6 is a schematic diagram of a circuit structure of another analog front-end chip provided in an embodiment of the present disclosure;

FIG. 7 is a schematic diagram of a circuit structure of another analog front-end chip provided in an embodiment of the present disclosure;

FIG. 8 is a schematic structural diagram of an oscilloscope provided in an embodiment of the present disclosure; and

FIG. 9 is a schematic structural diagram of a data collection system provided in an embodiment of the present disclosure.

In the drawings:
1. analog front-end chip; 11. input buffer module; 111. input buffer; 12. variable gain amplification module; 121. variable gain amplifier; 122. multi-input variable gain amplifier; 13. output branch; 131. output buffer module; 1301. first input end; 1302. second input end; 1311. amplification circuit; 14. first filter; 15. second filter; 16. third filter; 17. control module.

### DETAILED DESCRIPTION

To help those skilled in the art better understand technical solutions of the present disclosure, the technical solutions in the embodiments of the present disclosure will be clearly and completely described below with reference to the accompanying drawings of the embodiments of the present disclosure. The embodiments described are merely part of the embodiments of the present disclosure and are not all of them. All other embodiments derived by those skilled in the art based on the embodiments of the present disclosure without creative work should fall within the scope of protection of the present disclosure.

It should be noted that the terms “first”, “second”, etc., used in the description, claims and the drawings of the present disclosure are for distinguishing similar objects and do not necessarily describe a specific order or sequence. It should be understood that data so used are interchangeable where appropriate, so that the embodiments of the present disclosure described herein can be implemented in sequences other than those illustrated or described herein. In addition, the terms “include/comprise”, and “have” and any variations thereof are intended to cover non-exclusive inclusion, for example, a process, method, system, product, or device that includes a series of steps or units is not necessarily limited to those steps or units that are clearly listed, but may include other steps or units that are not clearly listed or inherent to the process, method, product, or device. In addition, unless otherwise specified, a singular form encompasses a plural form.

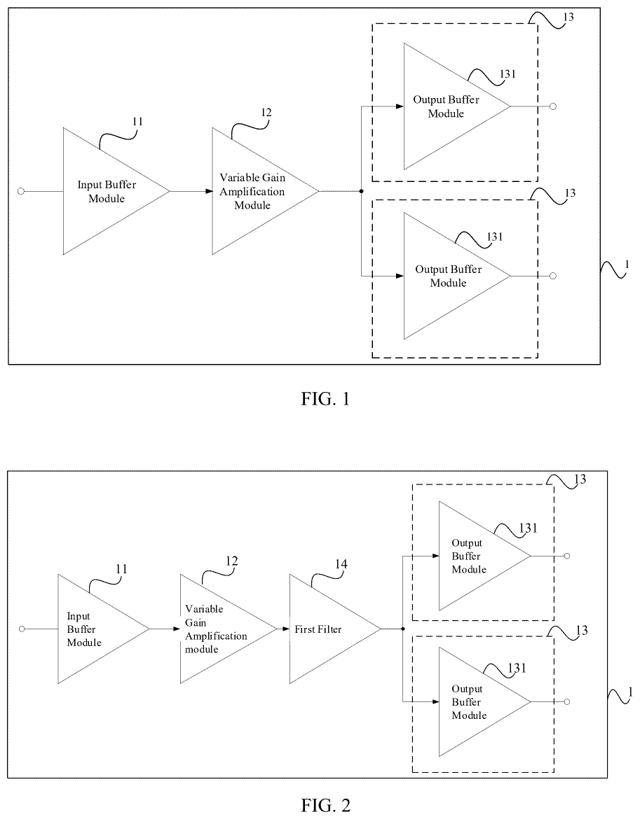

FIG. 1 is a schematic diagram of a circuit structure of an analog front-end chip provided in an embodiment of the present disclosure. Referring to FIG. 1, the analog front-end chip 1 is integrated with an input buffer module 11, a variable gain amplification module 12, and at least two output branches 13. An input end of the input buffer module 11 is configured as an input end of the analog front-end chip 1, and an output end of the input buffer module 11 is electrically connected to an input end of the variable gain amplification module 12. An input end of each output branch 13 is electrically connected to an output end of the variable gain amplification module 12, and an output end of each output branch 13 is configured as an output end of the analog front-end chip 1, wherein each output branch 13 includes an output buffer module 131.

Alternatively, in this embodiment, the circuit structures of the analog front-end chip 1 are all integrated on one chip, which are prepared by adopting integrated circuit technology instead of discrete devices, thereby significantly reducing the occupied area. Meanwhile, integrated circuit technology is adopted, which can also reduce losses, thereby facilitating achieving high bandwidth. The input buffer module 11 is disposed for impedance transformation. In the 50Ω path of the oscilloscope, the input buffer module 11 has a relatively high input impedance, and the overall impedance of the oscilloscope is determined by a terminal resistor. Similarly, in the 1Ω path of the oscilloscope, the input impedance is also determined by the terminal resistor. The input buffer module 11 can consist of an amplifier with the amplification capability, thereby realizing coarse adjustment of the sensitivity. In addition, the input buffer module 11 may provide a relatively high input impedance to reduce the impact of the oscilloscope on the measured signal and buffer the measured signal to output it to the subsequent variable gain amplification module 12. It should be noted that the amplification factor of the input buffer module 11 can be greater than or equal to 1, or less than 1. When the amplification factor is greater than 1, the input buffer module 11 may have an amplification function, and when the amplification factor is less than 1, the input buffer module 11 may have an attenuation function. The variable gain amplification module 12 may have a plurality of gain levels for amplifying or attenuating signals output by the input buffer module 11 with different amplitudes, thereby realizing further adjustment of the sensitivity. In addition, the bandwidth of the variable gain amplification module 12 may have different configurations, so that it can perform bandwidth limitation function, and thus it can be set to filter out noise with relatively high frequency. Signals output by the variable gain amplification module 12 can be divided into a plurality of signals, which may be input into each output branch 13, respectively. That is, each output branch 13 of the analog front-end chip in this embodiment can output one signal, so that the oscilloscope can realize the interleaving function. Certainly, when the oscilloscope does not need the interleaving function, only one output branch 13 can be configured. In this embodiment, each output branch 13 may include an output buffer module 131 configured to buffer the signals output by the variable gain amplification module 12, thereby improving the driving capability. It should also be noted that the various signals described in this embodiment may be single-ended signals or differential signals. The differential signals can be adopted to effectively reduce the noise interference.

In a method of this embodiment, the analog front-end chip adopted is integrated with an input buffer module, a variable gain amplification module, and at least two output branches. An input end of the input buffer module is configured as an input end of the analog front-end chip, and an output end of the input buffer module is electrically connected to an input end of the variable gain amplification module. An input end of each output branch is electrically connected to an output end of the variable gain amplification module, and an output end of each output branch is configured as an output end of the analog front-end chip, wherein each output branch includes an output buffer module. The adoption of the integrated chip can effectively reduce the occupied area and damage, thus facilitating achieving high bandwidth. At the same time, at least two output branches are adopted, so that the oscilloscope can realize the interleaving function. In addition, each output branch includes an output buffer module, which can greatly improve the driving capability of the analog front-end chip.

Alternatively, continuing to refer to FIG. 1, the input end of the output buffer module 131 is configured as the input end of the output branch 13 corresponding to the output buffer module 131, and the output end of the output buffer module 131 is configured as the output end of the output branch 13 corresponding to the output buffer module 131.

Alternatively, the output branch 13 in this embodiment can only be composed of an output buffer module 131. The number of components included in the analog front-end chip 1 is small and the analog front-end chip 1 has a simple structure, which is more conducive to reduce the occupied area of the analog front-end chip 1 and effectively reduce parasitic parameters at the same time. Exemplarily, the output buffer module 131 can be composed of an amplification circuit 1311. The amplification circuit can be a circuit capable of realizing an amplification function, for example, a basic operational amplification circuit, or a common emitter amplification circuit, etc. Of course, it can also be a radio frequency amplification circuit. A specific circuit structure and working principle of the amplification circuit 1311 are well known to those skilled in the art and will not be described in detail here.

Alternatively, FIG. 2 is a schematic diagram of a circuit structure of another analog front-end chip provided in an embodiment of the present disclosure. The analog front-end chip 1 is also integrated with a first filter 14. The input end of each output branch 13 is electrically connected to the output end of the variable gain amplification module 12 via the first filter 14, where the output end of the variable gain amplification module 12 is electrically connected to an input end of the first filter 14, and an output end of the first filter 14 is electrically connected to the input end of each output branch 13.

Alternatively, the first filter 14 may be composed of an inductor, a capacitor, and a resistor, and the first filter 14 may be a low-pass filter or a band-pass filter, thereby filtering out high-frequency noise and improving the noise performance of the analog front-end chip 1. A specific bandwidth of the first filter 14 may be differently designed according to different application scenarios. In addition, a specific circuit structure of the filter is well-known to those skilled in the art and will not be described in detail here.

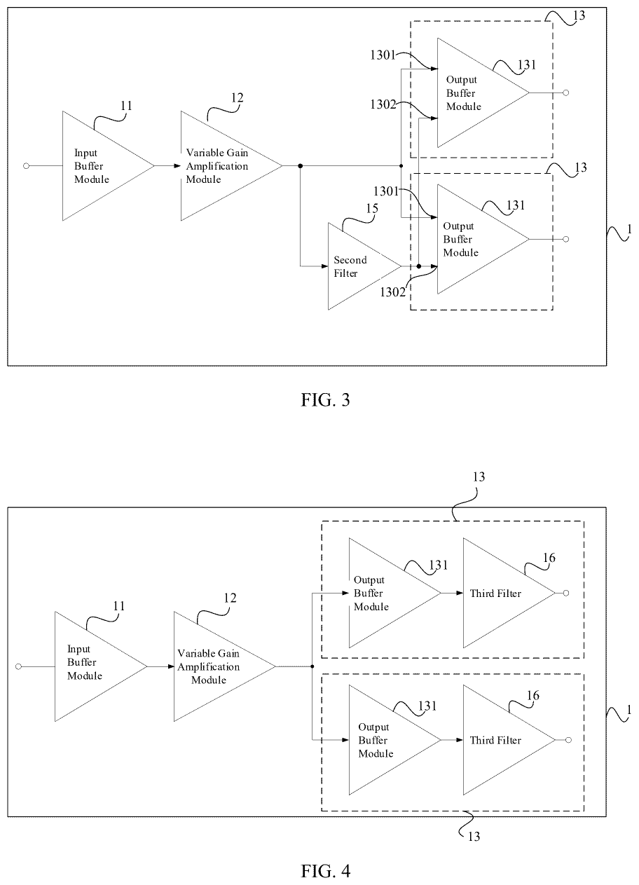

Alternatively, FIG. 3 is a schematic diagram of a circuit structure of another analog front-end chip provided in an embodiment of the present disclosure. Referring to FIG. 3, the analog front-end chip 1 is also integrated with a second filter 15. The output buffer module 131 includes a first input end 1301 and a second input end 1302. The first input end 1301 of the output buffer module 131 is configured as an input end of an output branch 13 corresponding to the output buffer module 131, and the output end of the output buffer module 131 is configured as an output end of the output branch 13 corresponding to the output buffer module 131. The output end of the variable gain amplification module 12 is electrically connected to an input end of the second filter 15, and an output end of the second filter 15 is electrically connected to the second input end 1302 of each output buffer module 131.

Alternatively, in this embodiment, the output buffer module 131 is a multi-input structure. The variable gain amplification module 12 may have a path directly to the output buffer module 131, and the path can ensure that the oscilloscope has a maximum bandwidth. The variable gain amplification module 12 may also have a path to the output buffer module 131 via the second filter 15, and the path also has a bandwidth limitation function due to the existence of the filter. That is, the analog front-end chip 1 in this embodiment can both guarantee the maximum bandwidth and have the bandwidth limitation function. It should be noted that similar to the first filter, the second filter 15 can be a low-pass filter or a band-pass filter, and the specific bandwidth can be differently designed according to different application scenarios.

Alternatively, FIG. 4 is a schematic diagram of a circuit structure of another analog front-end chip provided in an embodiment of the present disclosure. Referring to FIG. 4, each output branch 13 may also include a third filter 16. The input end of the output buffer module 131 is configured as the input end of the output branch 13 corresponding to the output buffer module 131. An output end of the output buffer module 131 is electrically connected to an input end of the third filter 16, and an output end of the third filter 16 is configured as an output end of the output branch 13 corresponding to the output buffer module 131.

Alternatively, the output buffer module 131 has certain noise besides the required bandwidth of the oscilloscope, and an output signal of the output buffer module 131 is directly configured as the output of the analog front-end chip 1, which may cause certain noise. Therefore, by setting the third filter 16 that may be a low-pass filter or a band-pass filter, high-frequency noise can be filtered out, so that the analog front-end chip 1 has the best noise performance.

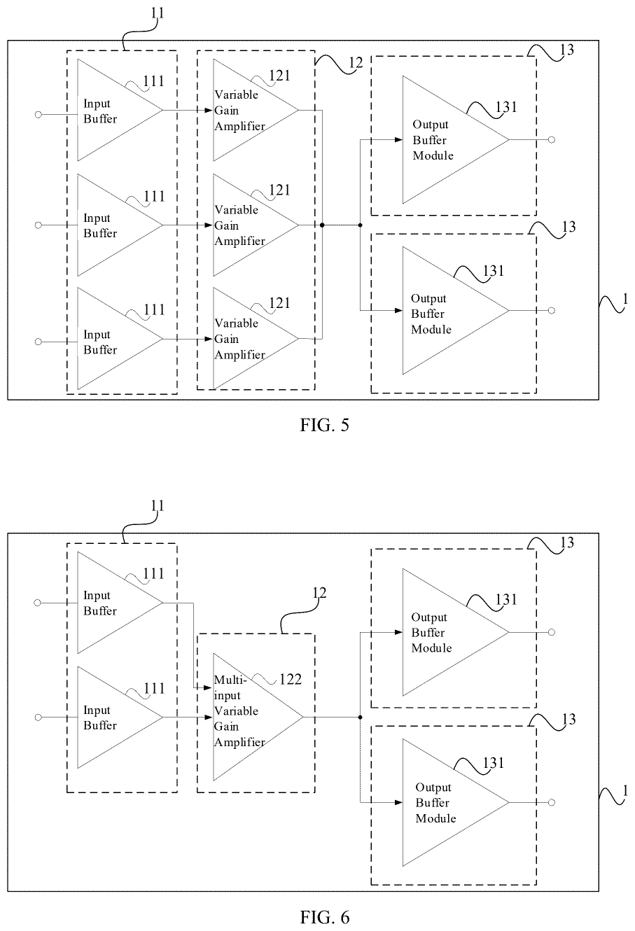

Alternatively, FIG. 5 is a schematic diagram of a circuit structure of another analog front-end chip provided in an embodiment of the present disclosure. Referring to FIG. 5, the input buffer module 11 may include a plurality of input buffers 111. Different input buffers 111 may be set to have different gains, and different outputs of the input buffers 111 can be selected, thereby achieving different gain selections. In this embodiment, the input end of each input buffer 111 can be configured as an input end of the analog front-end chip 1. The input ends of the analog front-end chip 1 can be connected together by different relays or attenuators, ect., outside of the analog front-end chip 1.

In an embodiment, continuing to refer to FIG. 5, the variable gain amplification module 12 may include a plurality of variable gain amplifiers 121. The plurality of the variable gain amplifiers 121 may correspond to the plurality of input buffers 111 one by one. An output end of an input buffer 111 is electrically connected to an input end of a variable gain amplifier 121 corresponding to the input buffer 111, and output ends of the plurality of variable gain amplifiers 121 are electrically connected. In this embodiment, each variable gain amplifier 121 may have different gains, thereby achieving different gain selections. Certainly, in some other embodiments, a position of each variable gain amplifier 121 may be replaced by a plurality of variable gain amplifiers 121 connected in series, that is, the variable gain amplifier module 12 includes a plurality of groups of variable gain amplifiers, each group of variable gain amplifiers is composed of a plurality of variable gain amplifiers 121 connected in series. The plurality of groups of variable gain amplifiers correspond to the plurality of input buffers 111 one by one, the output end of the input buffer 111 is electrically connected to the input end of a corresponding variable gain amplifier 121, and the output ends of the plurality of groups of variable gain amplifiers are electrically connected.

Alternatively, FIG. 6 is a schematic diagram of a circuit structure of another analog front-end chip provided in an embodiment of the present disclosure. Referring to FIG. 6, in this embodiment, the variable gain amplification module 12 may include a multi-input variable gain amplifier 122, a plurality of input ends of the multi-input variable gain amplifier 122 may correspond to the plurality of input buffers 111 one by one. Different input ends of the multi-input variable gain amplifier 122 may correspond to different gains, thus different gains can be selected.

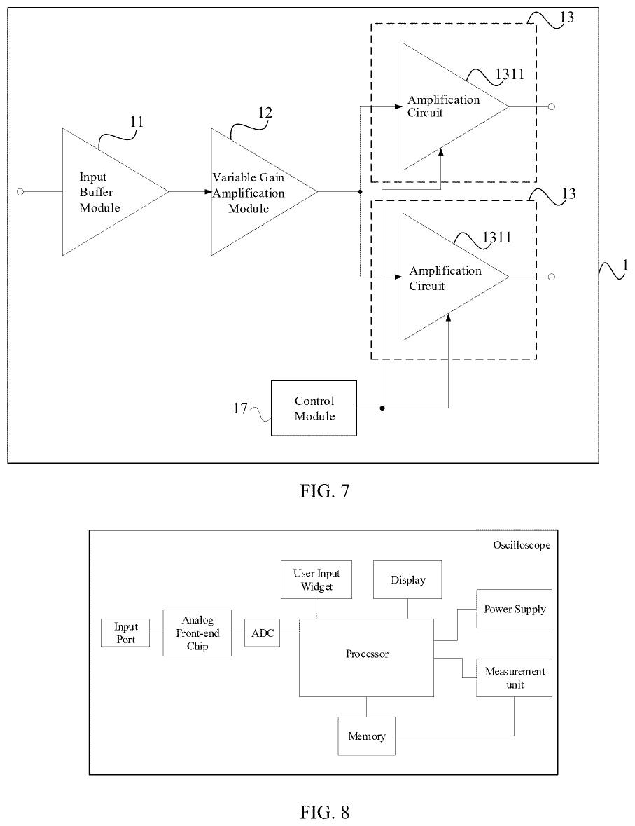

Alternatively, FIG. 7 is a schematic diagram of a circuit structure of another analog front-end chip provided in an embodiment of the present disclosure. Referring to FIG. 7, the output buffer module 131 may include an amplification circuit 1311. The analog front-end chip 1 is also integrated with a control module 17. The control module 17 may be connected to the amplification circuit 1311 and configured to control the output voltage of the amplification circuit 1311. Common mode voltage output by the amplification circuit 1311 may be controlled by the control module 17, that is, the amplification factor of the amplifier circuit 1311 is controlled by the control module 17, so as to meet different gain selections. Of course, in some other embodiments, the common mode voltage output by the amplification circuit 1311 may be commonly controlled by the control module 17 in the analog front-end chip 1 and a device outside the analog front-end chip 1. Or, the analog front-end chip 1 may be not integrated with the control module 17, and the common mode voltage output by the amplification circuit 1311 may be controlled by the device outside the analog front-end chip 1. For example, the common mode voltage may be controlled by a signal generated by a microcontroller unit (MCU) or FPGA.

This embodiment also provides an oscilloscope, as shown in FIG. 8, the oscilloscope may include the analog front-end chip provided in any embodiment of the present disclosure, which can be disposed between an input port of the oscilloscope and an analog-to-digital converter (ADC). The input port is configured to receive a signal from a connected device (e.g., a device under test (DUT), a circuit, a discrete device or a group of devices, or other objects under test), and the ADC is configured to convert the received analog signal into digital signal. The oscilloscope may also include a processor, a memory, a measurement unit, a user input widget, a display, a user input interface, and a power supply, etc. The processor may be configured to process the signal and/or waveform transmitted by the ADC, and may be configured to execute instructions from the memory. The memory may be configured to store the waveform generated by the processor, and may be a cache, a random access memory (RAM), a read-only memory (ROM), a solid-state memory, a hard drive, or any other types of memory. The memory acts as a medium for storing data, computer program products, and other instructions. Although illustrated as a single memory in the drawings, the memory may be implemented in a plurality of modules or separate memories. In addition, many components of the oscilloscope may include their own dedicated memory, and the processor may access these dedicated memories. The measurement unit may be coupled to the processor and is capable of measuring various aspects of the signal received through the input port (e.g., voltage, current intensity, amplitude, etc.). The display may be coupled to the processor and configured to display the waveform generated by the processor, a user input interface may be disposed thereon, and the display may be a digital screen, a display based on cathode ray tube, or any other monitor for displaying a waveform, measurement, and other data to a user. The user input widget may include a keyboard, a mouse, a trackball, a touch screen, and/or any other widget that a user may use to interact with the user input interface on the display. The power supply is configured to provide power to various components within the oscilloscope.

The oscilloscope may be a digital oscilloscope. Since the oscilloscope includes the analog front-end chip provided in any embodiment of the present disclosure, it has the same beneficial effects, which will not be described in detail here.

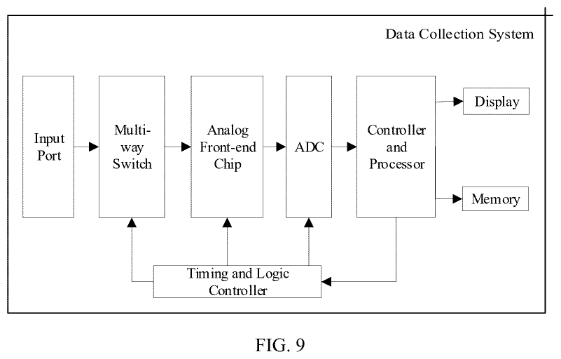

Certainly, in other implementations, the analog front-end chip can also be applied in a data collection system, as shown in FIG. 9. In addition to the analog front-end chip described in the above embodiments, the data collection system may include an input port, a multi-way switch, an ADC, a controller and processor, a timing and logic controller, a display and a memory, etc., where the multi-way switch can be configured to select a signal transmitted by the input port according to the demand, and transmit the selected signal to the analog front-end chip, and the timing and logic controller can be configured to perform logic control on the multi-way switch, the analog front-end chip, the ADC, the controller and processor. The functions of the input port, the ADC, the processor, the display and the memory are basically the same as those of the input port, the ADC, the processor, the display and the memory described in FIG. 8, respectively. For the detailed description of the components such as the multi-way switch, the controller, the timing and logic controller, etc., reference can be made to the corresponding description in the prior art, which will not be described in detail here.

Each embodiment in this specification is described in a progressive manner, and the same and similar parts between the embodiments can be referred to each other, and each embodiment focuses on the differences from other embodiments. In addition, the technical features of the above embodiments can be combined arbitrarily. In order to make the description concise, all possible combinations of the technical features in the above embodiments are not described. However, as long as there is no contradiction in the combination of these technical features, they should be considered to fall within the scope of this specification.

The above specific implementations do not constitute a limitation on the protection scope of the present disclosure. Those skilled in the art should understand that various modifications, combinations and substitutions can be made according to design requirements and other factors. Any modifications, equivalent substitutions and improvements made within the spirit and principles of the present disclosure should be included in the protection scope of the present disclosure.

1. An analog front-end chip, wherein
the analog front-end chip is integrated with an input buffer module, a variable gain amplification module, and at least two output branches;
an input end of the input buffer module is configured as an input end of the analog front-end chip, and an output end of the input buffer module is electrically connected to an input end of the variable gain amplification module;
an input end of each of the output branches is electrically connected to an output end of the variable gain amplification module, and an output end of each of the output branches is configured as an output end of the analog front-end chip; and
each of the output branches comprises an output buffer module.

2. The analog front-end chip of claim 1, wherein
an input end of the output buffer module is configured as an input end of an output branch corresponding to the output buffer module, and an output end of the output buffer module is configured as an output end of the output branch corresponding to the output buffer module.

3. The analog front-end chip of claim 2, wherein
the analog front-end chip is integrated with a first filter, and
the input end of each of the output branches is electrically connected to the output end of the variable gain amplification module via the first filter, wherein the output end of the variable gain amplification module is electrically connected to an input end of the first filter, and an output end of the first filter is electrically connected to the input end of each of the output branches.

4. The analog front-end chip of claim 1, wherein
the first filter comprises a low-pass filter or a band-pass filter.

5. The analog front-end chip of claim 1, wherein
the analog front-end chip is integrated with a second filter,
the output buffer module comprises a first input end and a second input end, the first input end of the output buffer module is configured as an input end of an output branch corresponding to the output buffer module, and an output end of the output buffer module is configured as an output end of the output branch corresponding to the output buffer module, and
the output end of the variable gain amplification module is electrically connected to an input end of the second filter, and an output end of the second filter is electrically connected to the second input of each output buffer module.

6. The analog front-end chip of claim 5, wherein
the second filter comprises a low-pass filter or a band-pass filter.

7. The analog front-end chip of claim 1, wherein
each of the output branches further comprises a third filter, and
an input end of the output buffer module is configured as an input end of an output branch corresponding to the output buffer module, an output end of the output buffer module is electrically connected to an input end of the third filter, and an output end of the third filter is configured as an output end of the output branch corresponding to the output buffer module.

8. The analog front-end chip of claim 7, wherein
the third filter comprises a low-pass filter or a band-pass filter.

9. The analog front-end chip of claim 1, wherein the input buffer module comprises a plurality of input buffers.

10. The analog front-end chip of claim 9, wherein
the variable gain amplification module comprises a plurality of variable gain amplifiers, the plurality of variable gain amplifiers correspond to the plurality of input buffers one by one, and
an output end of an input buffer is electrically connected to an input end of a variable gain amplifier corresponding to the input buffer, and output ends of the plurality of variable gain amplifiers are electrically connected.

11. The analog front-end chip of claim 10, wherein
the plurality of variable gain amplifiers have different gains.

12. The analog front-end chip of claim 9, wherein
the variable gain amplification module comprises a plurality of groups of variable gain amplifiers, each group of the variable gain amplifiers comprises a plurality of variable gain amplifiers connected in series, and the plurality of groups of variable gain amplifiers correspond to the plurality of input buffers one by one.

13. The analog front-end chip of claim 9, wherein
the variable gain amplification module comprises a multi-input variable gain amplifier, and
a plurality of input ends of the multi-input variable gain amplifier correspond to the input buffers one by one.

14. The analog front-end chip of claim 9, wherein
the plurality of variable gain amplifiers have different gains.

15. The analog front-end chip of claim 1, wherein the output buffer module comprises an amplification circuit.

16. The analog front-end chip of claim 15, wherein
the analog front-end chip is integrated with a control module,
the control module is connected to the amplification circuit and configured to control output voltage of the amplification circuit.

17. The analog front-end chip according to claim 16, wherein
a common mode voltage output by the amplification circuit is controlled by the control module and a device outside the analog front-end chip.

18. The analog front-end chip according to claim 15, wherein
a common mode voltage output by the amplification circuit is controlled by a device outside the analog front-end chip.

19. An oscilloscope, comprising an analog front-end chip integrated with an input buffer module, a variable gain amplification module, and at least two output branches, wherein
an input end of the input buffer module is configured as an input end of the analog front-end chip, and an output end of the input buffer module is electrically connected to an input end of the variable gain amplification module;
an input end of each of the output branches is electrically connected to an output end of the variable gain amplification module, and an output end of each of the output branches is configured as an output end of the analog front-end chip; and
each of the output branches comprises an output buffer module.

20. A data collection system, comprising an analog front-end chip integrated with an input buffer module, a variable gain amplification module, and at least two output branches, wherein
an input end of the input buffer module is configured as an input end of the analog front-end chip, and an output end of the input buffer module is electrically connected to an input end of the variable gain amplification module;
an input end of each of the output branches is electrically connected to an output end of the variable gain amplification module, and an output end of each of the output branches is configured as an output end of the analog front-end chip; and
each of the output branches comprises an output buffer module.
